(19) United States
(12) Patent Application Publication
(10) Pub. No.: US 2017/0170108 A1
(43) Pub. Date: Jun. 15, 2017

(54) CHIP CARRIER HAVING VARIABLY-SIZED PADS

(71) Applicant: Intel Corporation, Santa Clara, CA (US)

(72) Inventors: Chee Ling WONG, Kuala Lumpur (MY); Chun Mun LAM, Bukit Mertajam (MY); Lee WEI CHUNG, Nibong Teba (MY); Mun Leong LOKE, Bukit Mertajam (MY); Kang Eu ONG, Simpang Ampat (MY)

(21) Appl. No.: 14/970,290

(22) Filed: Dec. 15, 2015

(51) Int. Cl. H01L 23/498; B23K 35/02; H01L 21/48; B23K 1/00; H01L 23/00; H01L 23/66

(52) U.S. Cl. CPC H01L 23/49838; H01L 24/17; H01L 23/66; H01L 21/4853; H01L 23/49816; H01L 24/81; B23K 1/0016; B23K 35/0244; H01L 2224/16227; H01L 2924/1532; H01L 2924/1511; H01L 2924/14; H01L 2224/1713; H01L 2223/6605; H01L 2224/16238; H01L 2224/81193

(57) ABSTRACT

Chip carriers having variably-sized solder pads, and integrated circuit packages incorporating such chip carriers are described. In an example, an integrated circuit package includes an integrated circuit electrically connected with a chip carrier having solder pads of different sizes. The integrated circuit may deliver high speed signals to smaller solder pads and low speed signals to larger solder pads. More particularly, the solder pads having smaller pad dimensions may better match impedance of a high speed signal line as compared to the solder pads having larger pad dimensions.

### TECHNICAL FIELD

Embodiments described herein generally relate to the field of integrated circuit packages and, in particular, chip carriers having solder pads sized to match impedance of a signal line.

### BACKGROUND

Integrated circuit packages are used for protecting an integrated circuit chip or die, and also to provide the chip or die with a physical and electrical interface to external circuitry. An integrated circuit packages may incorporate a chip carrier, such as a ball grid array (BGA) component, for the chip or die. The BGA component usually includes solder pads having identical sizes across an entire package surface. Typically, the size of the solder pads are selected to ensure mechanical integrity of the integrated circuit package when the BGA component is mounted on an external substrate, e.g., a printed circuit board (PCB).

### BRIEF DESCRIPTION OF THE DRAWINGS

FIG. 1 illustrates a sectional view of an integrated circuit package, in accordance with an embodiment.

FIG. 2 illustrates a perspective view of several signal lines of a ball grid array (BGA) component, in accordance with an embodiment.

FIG. 3 illustrates a plan view of several signal lines of a BGA component, in accordance with an embodiment.

FIG. 4 illustrates a perspective view of several signal lines of a BGA component, in accordance with an embodiment.

FIG. 5 illustrates a plan view of a ball field of a BGA component, in accordance with an embodiment.

FIGS. 6A-6C illustrates partial plan views of a ball field of a BGA component, in accordance with an embodiment.

FIG. 7 illustrates a graphical view of a return loss for variably-sized solder pads of a BGA component, in accordance with an embodiment.

FIG. 8 illustrates a graphical view of an insertion loss for variably-sized solder pads of a BGA component, in accordance with an embodiment.

FIG. 9 illustrates a flowchart of a method of manufacturing an integrated circuit package incorporating a BGA component having variably-sized solder pads, in accordance with an embodiment.

FIG. 10 is a schematic of a computer system, in accordance with an embodiment.

### DESCRIPTION OF EMBODIMENTS

Chip carriers, such as ball grid array (BGA) components, having solder pads of different sizes, and integrated circuit packages incorporating such chip carriers, are described. In the following description, numerous specific details are set forth, such as packaging and interconnect architectures, in order to provide a thorough understanding of embodiments of the present invention. It will be apparent to one skilled in the art that embodiments of the present invention may be practiced without these specific details. In other instances, well-known features, such as specific semiconductor fabrication processes, are not described in detail in order to not unnecessarily obscure embodiments of the present invention. Furthermore, it is to be understood that the various embodiments shown in the Figures are illustrative representations and are not necessarily drawn to scale.

Existing chip carriers of integrated circuit packages may include a multi-layered package substrate, and electrical interconnects may transfer electrical signals through the package substrate between an integrated circuit chip or die and solder pads of the chip carrier. Parasitic capacitance can form between the solder pads and a ground plane of the multi-layered package substrate, causing an impedance mismatch between the fixed-size solder pads of the chip carrier and an interconnect, e.g., a plated-through hole, in the package substrate. Furthermore, as signal speeds of a chip or die of an integrated circuit package increase, e.g., to provide serializer/deserializer (SerDes) functionality, the impedance mismatch may cause reflection losses and degrade the high speed signal performance. To compensate for the parasitic capacitance and improve the impedance matching of the interface, an opening may be formed between the ground plane and the solder pads. That is, voids may be formed in the package substrate around the solder pads. Such structural modifications to the package substrate may, however, lead to warpage and delamination issues that negatively affect the physical and electrical interface between the integrated circuit package and external circuitry.

In an aspect, a chip carrier having variably-sized solder pads improves impedance matching of solder pads used for high speed signals, and thus, the chip carrier meets high speed signal requirements. In an embodiment, a chip carrier includes two or more sets of solder pads having respective pad dimensions, i.e., distances across pad surfaces. For example, a first set of solder pads may include a pad diameter of 630 microns and a second set of solder pads may include a pad diameter of 470 microns. The smaller pads of the second set may reduce parasitic capacitance, and thus, may improve impedance matching for their respective signal lines. The larger pads may be used to maintain mechanical integrity of the package, e.g., the larger pads may be located along an outer column and/or outer row of a ball field of the chip carrier where mechanical stress tends to localize. Thus, chip carriers having solder pads of different sizes, and integrated circuit packages incorporating such chip carriers, may improve high speed signal routing without negatively affecting the physical and electrical interface between the integrated circuit package and external circuitry. From a manufacturing perspective, such a solution may be easier to implement than forming openings in the package substrate, and thus, the solution can also lead to cost savings over existing solutions.

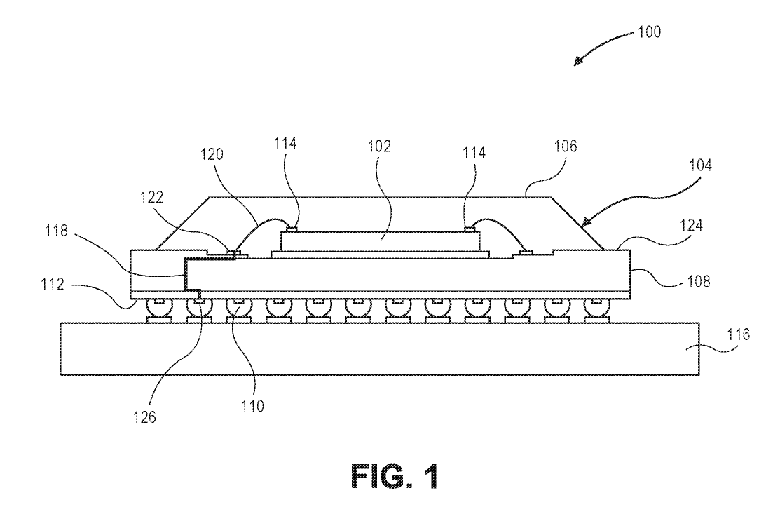

Referring to FIG. 1, a sectional view of an integrated circuit package is illustrated in accordance with an embodiment. An integrated circuit package 100 may include an integrated circuit 102 packaged within a chip carrier. As shown, the integrated circuit package 100 may include a wire-bonding package, however, it will be appreciated by one skilled in the art that other non-wire bonding packages may be used in accordance with the description below. The chip carrier may be a BGA component 104 having a top package portion 106, e.g., a plastic cap, over a package substrate 108, e.g., a ceramic or laminate substrate. BGA component 104 may include several pins, e.g., several solder balls 110, arranged in a ball field. The ball field may include a solder ball array, i.e., solder balls 110 arranged on package substrate 108 in a pattern. For example, the in the case of BGA component 104, the pattern may include a grid pattern. The grid pattern is illustrated by way of example, since other chip carriers having non-gridded ball patterns may be used, as is known in the art. Thus, although the following description applies in a general sense to any type of chip carrier, the description will refer to BGA component 104 for consistency in the description. In an embodiment, the grid pattern includes solder balls 110 uniformly spaced within several rows and columns. For example, solder balls 110 may be located in a coordinate grid system having a pitch of 500 microns between each adjacent solder ball 110. Solder balls 110 arranged in the grid pattern may cover essentially all of a first surface 112 of package substrate 108. Alternatively, portions of first surface 112 may be depopulated, e.g., a central rectangular region on first surface 112 may not include solder balls 110.

Each solder ball 110 may be electrically connected to integrated circuit 102 to provide an electrical function. For example, solder balls 110 near a center of package substrate 108 may be electrically connected to a pin 114, e.g., a signal pin used for I/O, of integrated circuit 102, and solder balls 110 near a periphery of package substrate 108 may be electrically connected to another pin 114 of integrated circuit 102 used as power and/or ground pins. Furthermore, solder balls 110 may be mounted and attached to a circuit board 116, e.g., a motherboard or another printed circuit board of a computer system, to provide a physical and electrical interface between integrated circuit 102 and circuit board 116.

The electrical connection between solder balls 110 of BGA component 104 and pins 114 of integrated circuit 102 may be through an interconnect 118 and/or a lead 120. More particularly, lead 120 may electrically connect pins 114 of integrated circuit 102 to one or more bonding pads 122 mounted on a second surface 124 of package substrate 108. Second surface 124 may be a surface opposite from first surface 112 on a same side of package substrate 108 as integrated circuit 102. Thus, lead 120 include a wire having ends soldered to a respective pin 114 on integrated circuit 102 and to a respective bonding pad 122 on second surface 124. Accordingly, several pins 114 of integrated circuit 102 may be electrically connected to several corresponding bonding pads 122 on second surface 124.

Bonding pads 122 mounted on second surface 124 may be electrically connected to corresponding solder pads 126 on first surface 112. More particularly, a solder pad 126 may be mounted on first surface 112 of package substrate 108, and solder pad 126 may be electrically connected to bonding pad 122 through interconnect 118. As described below, solder pads 126 may include flat surfaces etched into a layer of package substrate 108, and corresponding solder balls 110 may be attached to the flat surfaces. Thus, pins 114 of integrated circuit 102 may be electrically connected to solder balls 110 through a signal line that includes interconnect 118 extending from bonding pad 122 on second surface 124 through package substrate 108 to solder pad 126 on first surface 112.

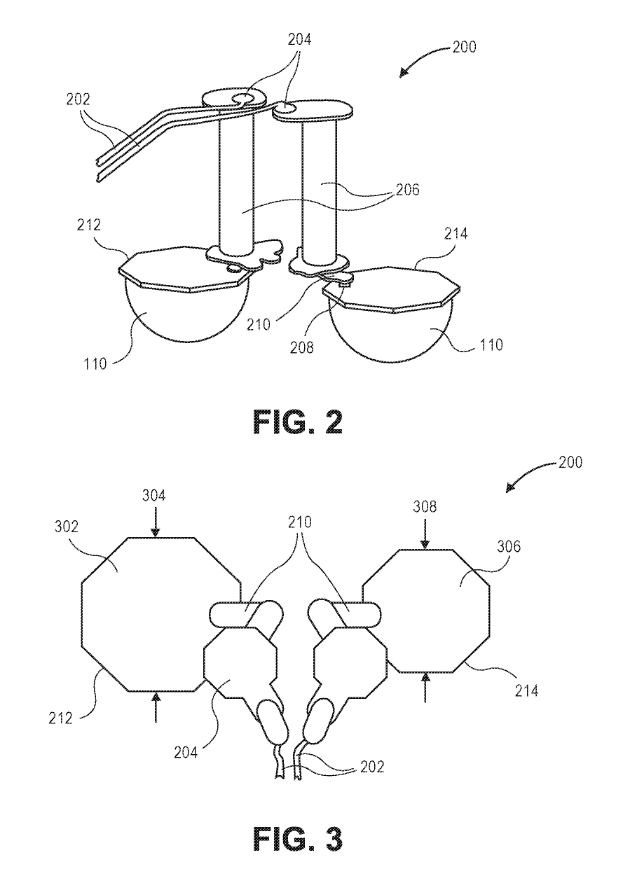

Referring to FIG. 2, a perspective view of several signal lines of a BGA component is illustrated in accordance with an embodiment. A signal line 200 of integrated circuit package 100 may include a signal trace 202 extending from bonding pad 122 on second surface 124 of package substrate 108 (not shown) to a front side via 204. Front side via 204 may extend through one or more layer of package substrate 108 from second surface 124. In an embodiment, front side via 204 may electrically connect to a plated-through hole 206 extending through one or more layer of package substrate 108. More particularly, plated-through hole 206 may extend to backside routing. Backside routing may include one or more back side via 208 and/or one or more back side trace 210. Backside routing may electrically connect plated-through hole 206 of interconnect 118 to a corresponding solder pad 126. Thus, a first solder pad 212 may be electrically connected to a corresponding bonding pad 122 through a first signal line 200, and a second solder pad 214 may be electrically connected to a corresponding bonding pad 122 through a second signal line 200. Similarly, the corresponding bonding pads 122 may be electrically connected to solder balls 110 attached to first solder pad 212 and second solder pad 214.

Referring to FIG. 3, a plan view of several signal lines of a BGA component is illustrated in accordance with an embodiment. As described above, solder balls 110 may be arranged in a grid pattern on first surface 112, and thus, the underlying solder pads 126 mounted on first surface 112 may also be arranged in a grid pattern. In an embodiment, each solder pad 126 includes a respective shape or size. For example, solder pads 126 may be rectangular, octagonal, circular, or have any other shape. Similarly, solder pads 126 may have respective dimensions. For example, first solder pad 212 may include a first pad surface 302, e.g., a flat surface attached to a respective solder ball 110 or a flat surface attached to a respective backside routing. First pad surface 302 may include a first pad dimension 304, i.e., a distance across first pad surface 302 from one edge to an opposite edge. For example, when first pad surface 302 includes a circular shape, first pad dimension 304 may be a diameter of the circular shape. Similarly, when first pad surface 302 is an octagon, first pad dimension 304 may be a distance between a first side of the octagon and an opposite second side of the octagon. In an embodiment, first solder pad 212 includes first pad dimension 304 greater than 600 microns. For example, first pad dimension 304 may be 630 microns.

In an embodiment, second solder pad 214 includes a second pad surface 306 having a shape or size that differs from first pad dimension 304. For example, although second pad surface 306 and first pad surface 302 are illustrated as being octagonal in FIG. 3, the pad surfaces may differ, e.g., first pad surface 302 may be octagonal and second pad surface 306 may be circular. Similarly, the pad surfaces may be variably-sized as shown in FIG. 3. That is, the pad surfaces may have different sizes. In an embodiment, second solder pad 214 includes a second pad dimension 308 across second pad surface 306, and second pad dimension 308 is less than first pad dimension 304. For example, second pad dimension 308 may be less than 500 microns, e.g., 470 microns. Thus, BGA component 104 of integrated circuit package 100 may include variably-sized solder pads 126 that can be segmented into a set of one or more first solder pads 212 and one or more second solder pads 214 having different pad dimensions.

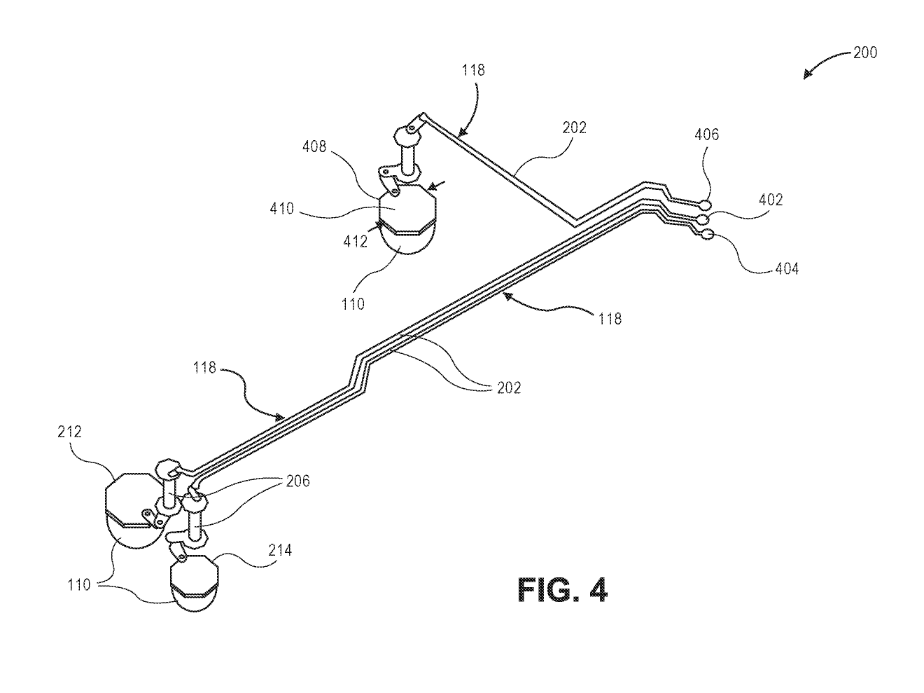

Referring to FIG. 4, a perspective view of several signal lines of a BGA component is illustrated in accordance with an embodiment. Signal lines 200 of integrated circuit package 100 and/or BGA component 104 are not limited to the structural configurations illustrated in FIGS. 2-3. More particularly, integrated circuit package 100 and/or BGA component 104 may include a signal line 200 electrically connecting solder ball 110 to a first bonding pad 402 or a second bonding pad 404 through a respective first solder pad 212 or second solder pad 214, and a corresponding interconnect having signal trace 202, plated-through hole 206, and one or more other interconnect 118 portions such as microvias. In an embodiment, signal lines 200 further include a signal line 200 electrically connecting solder ball 110 to a third bonding pad 406 through a third solder pad 408 and a corresponding interconnect 118. Third solder pad 408 may include a third pad surface 410, e.g., a flat surface attached to solder ball 110 or interconnect 118. In an embodiment, third pad surface 410 includes a shape or size that differs from that of first solder pad 212 and second solder pad 214. For example, third solder pad 408 may include a third pad dimension 412 across third pad surface 410, and third pad dimension 412 may be less than first pad dimension 304 and greater than second pad dimension 308. For example, third pad dimension 412 may be between 500 microns and 600 microns, e.g., 550 microns. Accordingly, BGA component 104 of integrated circuit package 100 may include variably-sized solder pads 126 that can be further segmented into a set of one or more third solder pads 408 having different pad dimensions than the set of first solder pads 212 and the set of second solder pads 214.

FIGS. 2-4 illustrate that solder pads 126 having different dimensions may be located adjacent to each other or may be separated from each other by one or more other solder pads 126. For example, as shown in FIG. 3, first solder pad 212 having a larger dimension may be located next to second solder pad 214 having a smaller dimension in the grid pattern of the ball field. By contrast, as shown in FIG. 4, first solder pad 212 having a larger dimension may be spaced apart from third solder pad 408 having an intermediate dimension in the grid pattern of the ball field.

As described below, solder pad 126 placement on first surface 112 may be selected based on an intended physical and/or electrical function of the solder pad 126. For example, first solder pads 212 having larger solder pad 126 dimensions may be dedicated to low speed signals, e.g., power/ground signals or I/O signals below a threshold frequency, and second solder pads 214 having smaller solder pad 126 dimensions may be dedicated to high speed signals, e.g., I/O signals above the threshold frequency. More particularly, the size of each solder pad 126 may be varied to match the impedance of a corresponding signal line carrying a signal that the solder pad 126 is intended to transmit and/or receive. Accordingly, solder pads 126 may be individually sized to improve the overall high speed performance of integrated circuit package 100.

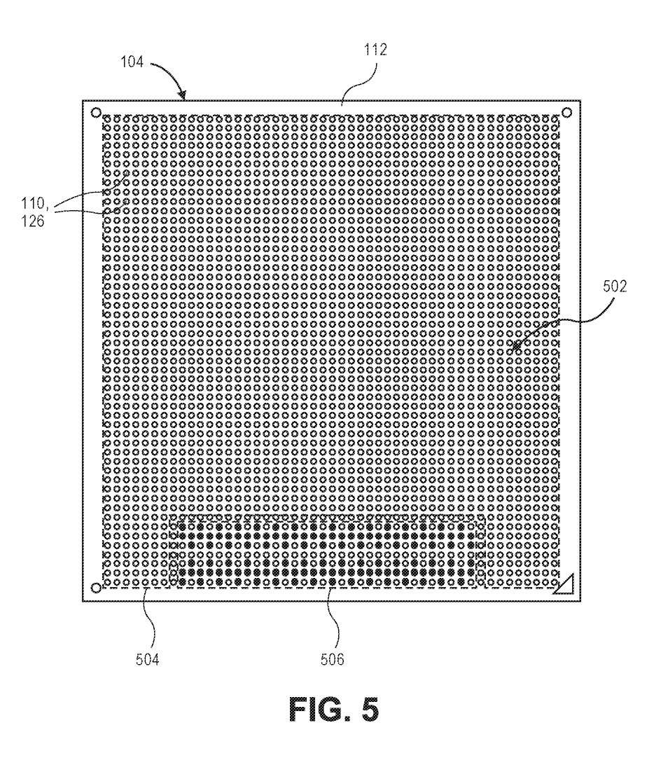

Referring to FIG. 5, a plan view of a ball field of a BGA component is illustrated in accordance with an embodiment. First surface 112 of BGA component 104 may include several sets of solder pads 126 distributed in a grid pattern 502 and attached to corresponding solder balls 110. In an embodiment, first surface 112 has a square profile, e.g., 45 mm by 45 mm, and grid pattern 502 includes solder pads 126 distributed evenly across first surface 112 with a 1 mm ball pitch. Accordingly, grid pattern 502 may include one or more rows, i.e., one or more solder pads 126 sequentially aligned from left to right across first surface 112 in FIG. 5. Furthermore, grid pattern 502 may include one or more columns of solder pads 126, i.e., one or more solder pads 126 sequentially aligned from top to bottom across first surface 112 in FIG. 5.

Solder pads 126 arranged in grid pattern 502 may be grouped into one or more grid blocks, i.e., sections of grid pattern 502 having a predetermined arrangement of solder pads 126. In an embodiment, a first grid block 504 refers to a region of grid pattern 502 that only incorporates solder pads 126 of a predetermined size. For example, first grid block 504 may only include first solder pads 212 having first pad dimensions 304, e.g., 630 microns. First solder pads 212 within first grid block 504 may not be separated from each other by a solder pad 126 having a different pad dimension. Grid pattern 502 may include a second grid block 506 that is distinguishable from first grid block 504. For example, second grid block 506 may refer to a region of grid pattern 502 that incorporates solder pads 126 having a different size than solder pads 126 that are repeatedly distributed within first grid block 504. Having differentiated between first grid block 504 and second grid block 506, various embodiments of grid blocks within grid pattern 502 are described below. It is noted that the following embodiments are provided by way of example to illustrate BGA component 104 having variably-sized solder pads 126, and are not limiting. For example, in each of the following approaches, second grid block 506 having second solder pads 214 for high speed signals is located in a bottom region of grid pattern 502, however, second grid block 506 may be located elsewhere in other embodiments.

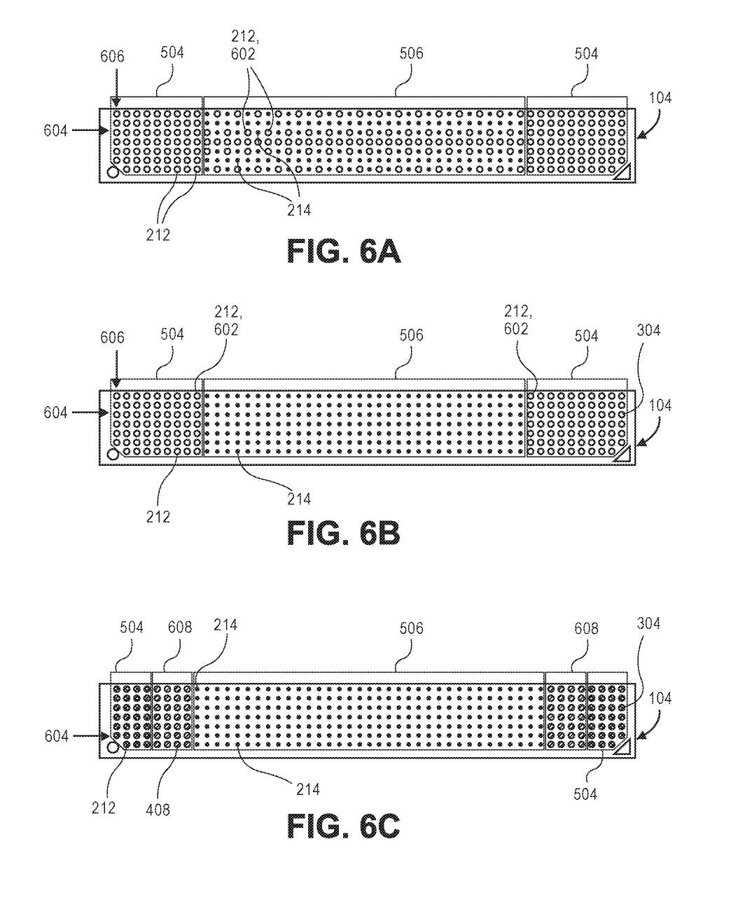

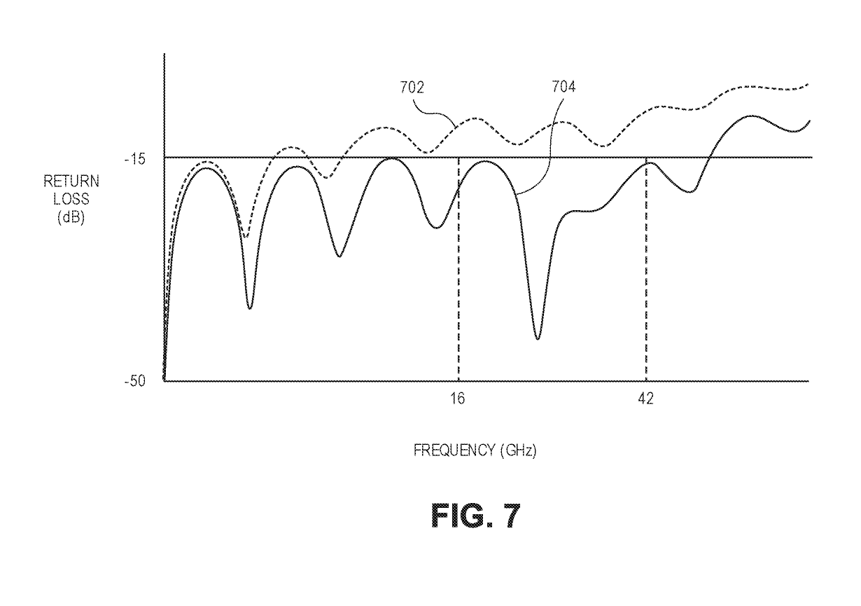

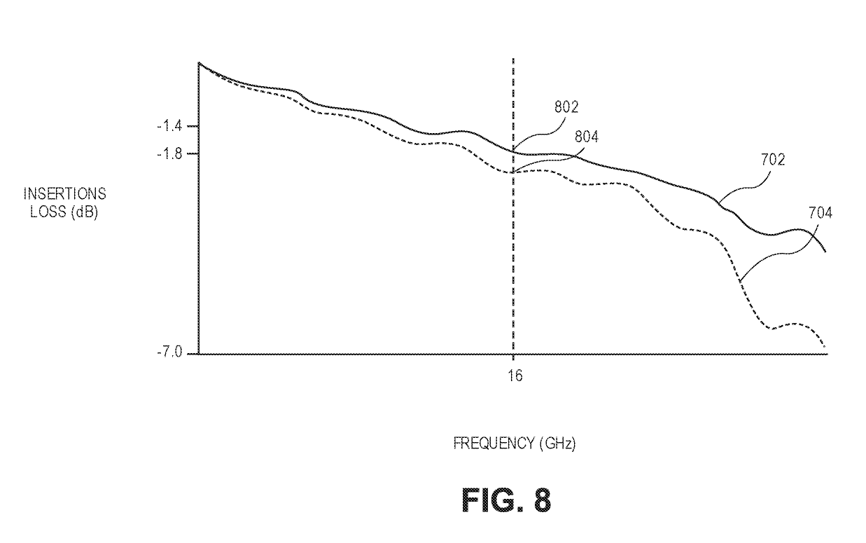

Referring to FIG. 6A, a partial plan view of a ball field of a BGA component is illustrated in accordance with an embodiment. First grid block 504 may incorporate first solder pads 212 having a first pad dimension 304, e.g., 630 microns, and second grid block 506 may incorporate a combination of first solder pads 212 and second solder pads 214. Second solder pads 214 may have a second pad dimension 308, e.g., 470 microns. One or more second solder pads 214 may be located in second grid block 506 and may be used to transmit and/or receive high speed I/O signals, i.e., I/O signals having a frequency above a predetermined threshold. By way of example, the predetermined threshold may be 16 GHz for the reasons described below with respect to FIGS. 7-8. By contrast, first solder pads 212 in second grid block 506 may be used to transmit and/or receive low speed I/O signals, i.e., I/O signals having a frequency below the predetermined threshold, or to ensure mechanical integrity of BGA component 104 as described below.

In an embodiment, one of the second solder pads 214 in second grid block 506 is located between a pair of first solder pads 602 in second grid block 506. For example, grid pattern 502 may include a row 604 of solder pads 126 sequentially aligned between an outer column 606 on a left side of BGA component 104 and an outer column on a right side of BGA component 104. At least two first solder pads 212 may be separated by one or more second solder pads 214 in row 604. In an embodiment, at least two first solder pads 212 or at least two second solder pads 214 may be separated by one or more third solder pads 408 in row 604. Thus, second grid block 506 may include any combination of variably-sized solder pads 126 located according to the I/O signals that the solder pads 126 are intended to carry. For example, in an embodiment, only solder pads 126 intended to carry high speed I/O signals may have pad dimensions less than 600 microns.

Referring to FIG. 6B, a partial plan view of a ball field of a BGA component is illustrated in accordance with an embodiment. First grid block 504 may incorporate first solder pads 212 having first pad dimension 304, e.g., 630 microns, and second grid block 506 may incorporate only second solder pads 214 having second pad dimension 308, e.g., 470 microns. Thus, instead of reducing a size of solder pads 126 used solely for high speed I/O signals within second grid block 506, a portion of the ball field may incorporate solder pads 126 having smaller dimensions that are intended to carry low speed I/O signals. More particularly, some second solder pads 214 in second grid block 506 may be used to carry signals with speeds above a predetermined threshold and some second solder pads 214 in second grid block 506 may be used to carry signals with speeds below the predetermined threshold. Such an arrangement may provide uniformity in the ball field of BGA component 104.

In an embodiment, second grid block 506 having a set of second solder pads 214 may be located between pair of first solder pads 602 in row 604. More particularly, second grid block 506 may separate a first portion of first grid block 504 having outer column 606 on a left side of BGA component 104 from a second portion of first grid block 504 having an outer column on a right side of BGA component 104. Thus, second grid block 506 may be located one or more rows (or columns) inward from outer column 606. Accordingly, outer column 606 of grid pattern 502 having variably-sized solder pads may incorporate solder pads 126 having larger dimensions along an outer row or outer column 606 to contribute to mechanical integrity of BGA component 104.

Referring to FIG. 6C, a partial plan view of a ball field of a BGA component is illustrated in accordance with an embodiment. First grid block 504 incorporating first solder pads 212 having first pad dimension 304, e.g., 630 microns, and second grid block 506 incorporating second solder pads 214 having second pad dimension 308, e.g., 470 microns, may be separated by a third grid block 608 having one or more third solder pads 408 with an intermediate pad dimension between first pad dimension 304 and second pad dimension 308, e.g., 550 microns. More particularly, one or more third solder pads 408 in third grid block 608 may be located between a first solder pad 212 within first grid block 504 and a second solder pad 214 within second grid block 506 in a row 604 of grid pattern 502. As shown, third grid block 608 may include one or more columns of third solder pads 408, and the column(s) of third solder pads 408 may be located between a column of first solder pads 212 in first grid block 504 and a column of second solder pads 214 in second grid block 506. Thus, one or more intermediately-sized solder pads 126 may be placed between one or more larger-sized solder pads 126 and one or more smaller-sized solder pads 126 to address any concern over a drastic change in solder pad size across grid pattern 502. More particularly, the intermediate size of third solder pad 408 may reduce the likelihood of poor mechanical or electrical performance caused by a sudden change in solder pad size.

In addition to locating solder pads 126 based on an intended signal speed function, solder pads 126 may be placed to ensure mechanical integrity of integrated circuit package 100. In an embodiment, solder joint stress in solder balls 110 attached to circuit board 116 is highest at the corners of integrated circuit package 100. More particularly, stresses in the solder joints tend to decrease exponentially from a corner-most solder ball 110, e.g., a solder ball 110 in an outer row and an outer column of grid pattern 502, toward a center of grid pattern 502. The localized high stress at the package corner may result from localized bending of circuit board 116. Thus, in an embodiment, solder pads 126 having smaller dimensions, such as second solder pads 214, may be located in a region of grid pattern 502 away from an outer row or an outer column. More particularly, first solder pads 212 having larger first pad dimension 304 may be located at the corners of grid pattern 502 and/or within an outer row or an outer column of grid pattern 502. Thus, first solder pads 212 having a larger dimension may be employed to maintain the mechanical integrity of integrated circuit package 100. Furthermore, appropriately located (i.e., not located at the package corner or the die shadow) second solder pads 214 having a smaller dimension may be employed to improve high speed signal performance of integrated circuit package 100 without negatively affecting mechanical integrity of integrated circuit package 100.

High speed signal performance of an embodiment of integrated circuit package 100 having BGA component 104 with variably-sized solder pads 126 has been characterized. By way of example, integrated circuit 102 may include a first signal pin 114 electrically connected to first solder pad 212. For example, the first signal pin 114 may be electrically connected to first bonding pad 402 in FIG. 4, which in turn is electrically connected to first solder pad 212. Similarly, a second signal pin 114 of integrated circuit 102 may be electrically connected to second solder pad 214 via second bonding pad 404, as shown in FIG. 4. As described above, first solder pad 212 may have a larger pad dimension than second solder pad 214. Thus, integrated circuit 102 may be configured to deliver a first electrical signal having a first frequency through the first signal pin 114 to first solder pad 212, and integrated circuit 102 may be configured to deliver a second electrical signal having a second frequency different than the first frequency through the second signal pin 114 to second solder pad 214. More particularly, the second frequency of the second electrical signal may be higher than the first frequency of the first electrical signal, i.e., the second electrical signal may have a higher speed than the first electrical signal. The smaller pad dimension of second solder pad 214 may provide an impedance that is better matched to the higher second frequency than the larger pad dimension of first solder pad 212. Furthermore, the improved impedance matching may result in an improvement in package usability to support high speed signals, as described further below.

Referring to FIG. 7, a graphical view of a return loss for variably-sized solder pads of a BGA component is illustrated in accordance with an embodiment. Signal loss may be minimized by impedance matching the variably-sized solder pads 126 to their corresponding signal lines 200. For example, return loss may be measured at bonding pads 122 and/or solder pads 126 of respective signal lines 200 to determine whether high speed signals may be supported by BGA component 104. Return loss may be defined as the signal loss caused by reflection of the signal within the signal line 200. In the graph of FIG. 7, return loss is measured in decibel (dB), and thus, higher values correspond to better loss characteristics (better performance). More particularly, a return loss of 15 dB may be arbitrarily selected as an acceptable return loss level at any given signal frequency as plotted against the horizontal axis. Thus, beginning at frequencies of about 16 GHz, first electrical signal 702 delivered to first solder pad 212 having a larger pad dimension, e.g., 630 microns, may experience unacceptable return losses. By contrast, second electrical signal 704 delivered to second solder pad 214 having a smaller pad dimension, e.g., 470 microns may experience acceptable return losses up to frequencies of about 42 GHz. That is, a return loss of second electrical signal 704 delivered to second solder pad 214 from the second signal pin 114 of integrated circuit 102 may be more than 15 dB when the second frequency is in a range of 20 GHz to 40 GHz. Such improved performance may be directly related to the solder pad 126 size as described above. Based on these results, a frequency of 16 GHz may be selected as a predetermined frequency threshold for distinguishing high speed and low speed signals. That is, solder pads intended to carry signals above 16 GHz may be referred to as high speed signal pads and solder pads intended to carry signals below 16 GHz may be referred to as low speed signal pads. High speed signal pads may have corresponding pad dimensions, e.g., may be second solder pads 214 having second pad dimensions 308, and low speed signal pads may have corresponding pad dimensions, e.g., may be first solder pads 212 having first pad dimensions 304. The predetermined frequency threshold of 16 GHz is provided by way of example, since other frequency thresholds distinguishing high speed and low speed signals may occur in products having different pad sizes as described herein.

Referring to FIG. 8, a graphical view of an insertion loss for variably-sized solder pads of a BGA component is illustrated in accordance with an embodiment. Another measure of signal speed performance is an insertion loss of the electrical signals delivered to solder pads 126 by integrated circuit 102. Insertion loss may be defined as a difference between the electrical signals input to bonding pads 122 or solder pads 126 compared to the electrical signal output at a corresponding solder pad 126 or bonding pad 122 on signal line 200. Thus, lower insertion loss indicates better performance of BGA component 104. The insertion loss corresponding to a signal line 200 having first solder pad 212 may be compared to the insertion loss corresponding to a signal line 200 having second solder pad 214 to assess the performance of the signal lines across a range of signal frequencies. For example, integrated circuit 102 may deliver the first electrical signal 702 to first solder pad 212 and the second electrical signal 704 to second solder pad 214, and when the electrical signals have identical frequencies, insertion loss of the corresponding signal lines 200 may be compared. By way of example, when the first electrical signal 702 and the second electrical signal 704 both have a frequency of 16 GHz, a first insertion loss 802 of the first electrical signal 702 delivered to first solder pad 212 is 0.4 dB more than a second insertion loss 804 of the second electrical signal 704 delivered to the second solder pad 214. Accordingly, second solder pad 214 better supports the 16 GHz signal than does first solder pad 212, and that comparative improvement can be seen at all frequencies as shown in FIG. 8.

Simulation of integrated circuit packages 100 and BGA components 104 having variably-sized solder pads 126 confirms that the improvement in signal loss described above is related to improved impedance matching. For example, Time Domain Reflectometry (TDR) results for signals delivered from first bonding pad 402 to first solder pad 212 having first pad dimension 304 of 630 microns, and signals delivered from second bonding pad 404 to second solder pad 214 having second pad dimension 308 of 470 microns, has shown an improvement in eye width of 2%, an improvement in eye height of 5%, and an improvement in jitter of 19%. One skilled in the art will recognize that these numbers confirm that the smaller second solder pad 214 is better matched to the impedance of the signal line 200 than the larger first solder pad 212. More particularly, such results confirm that the smaller solder pad 126 reduces the capacitive debt and provides a smoother impedance profile supportive of higher-speed signals.

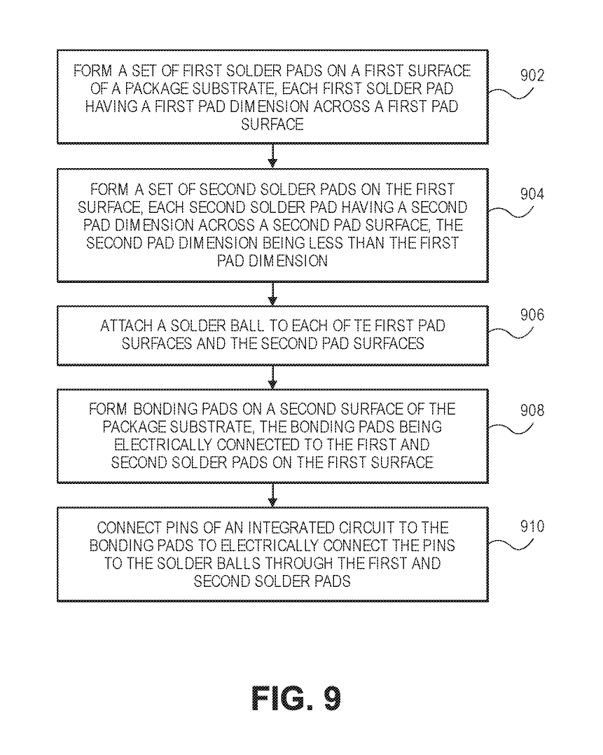

Referring to FIG. 9, a flowchart of a method of manufacturing an integrated circuit package incorporating a BGA component having variably-sized solder pads is illustrated in accordance with an embodiment. At operation 902, a set of first solder pads 212 may be formed on first surface 112 of package substrate 108. Each first solder pad 212 may include a same first pad dimension 304 across a respective first pad surface 302, e.g., 630 microns. Processing techniques for forming solder pads 126 are known, and thus, additional description shall not be provided here in the interest of brevity. At operation 904, a set of second solder pads 214 may be formed on first surface 112 of package substrate 108. Each second solder pad 214 may include a same second pad dimension 308 across a respective second pad surface 306, e.g., 470 microns. More particularly, second solder pads 214 may be formed to have a smaller size than first solder pads 212. The same processing techniques used to form first solder pads 212 may be used to form second solder pads 214 on first surface 112. In an embodiment, a set of third solder pads 408 may be formed on first surface 112 of package substrate 108. Each third solder pad 408 may include a same third pad dimension 412 across a respective third pad surface 410. Third pad dimension 412 may be an intermediate dimension, i.e., a dimension that is less than first pad dimension 304 and greater than second pad dimension 308.

At operation 906, solder balls 110 may be attached to the sets of solder pads 126. For example, a solder ball 110 may be attached to each of the first pad surfaces 302 and the second pad surfaces 306. Solder balls 110 may be uniformly sized and arranged in grid pattern 502 across first surface 112. Solder balls 110 may cover the variably-sized solder pads 126 of BGA component 104.

At operation 908, bonding pads 122 may be formed on second surface 124 of package substrate 108. Like solder pads 126, bonding pads 122 may be formed using known processing techniques. Furthermore, bonding pads 122 may be electrically connected to solder pads 126 on first surface 112 through interconnects 118, and processing techniques known for forming electrical interconnects 118 through package substrate 108 may be used to achieve such electrical connection. Specific description of the processing techniques are omitted here in the interest of brevity.

At operation 910, pins 114 of integrated circuit 102 may be connected to corresponding bonding pads 122 to electrically connect the pins 114 to solder balls 110 attached to corresponding solder pads 126. For example, pins 114 may be electrically connected to bonding pads 122 through the leads 120 using known wire bonding techniques. In an embodiment, a first pin 114 of integrated circuit 102 is electrically connected to first solder pad 212 through first bonding pad 402, and a second pin 114 of integrated circuit 102 is electrically connected to second solder pad 214 through second bonding pad 404.

Having fabricated integrated circuit package 100 incorporating BGA component 104 using the operations described above, integrated circuit package 100 may be used to provide various processing functions. For example, integrated circuit 102 may deliver a first electrical signal 702 through the first signal pin 114 electrically connected to first solder pad 212. More particularly, the first electrical signal 702 may be a low speed I/O signal, e.g., an I/O signal having a frequency below 16 GHz. similarly, integrated circuit 102 may deliver a second electrical signal 704 through the second signal pin 114 electrically connected to second solder pad 214. More particularly, the second electrical signal 704 may have a higher frequency than the first electrical signal 702. For example, the second electrical signal 704 may be a high speed I/O signal, e.g., an I/O signal having a frequency above 16 GHz. Thus, integrated circuit package 100 may be used to support high speed signal performance with improved signal loss characteristics as described above. For example, integrated circuit package 100 may be used to provide serializer/deserializer (SerDes) functionality for a computer system.

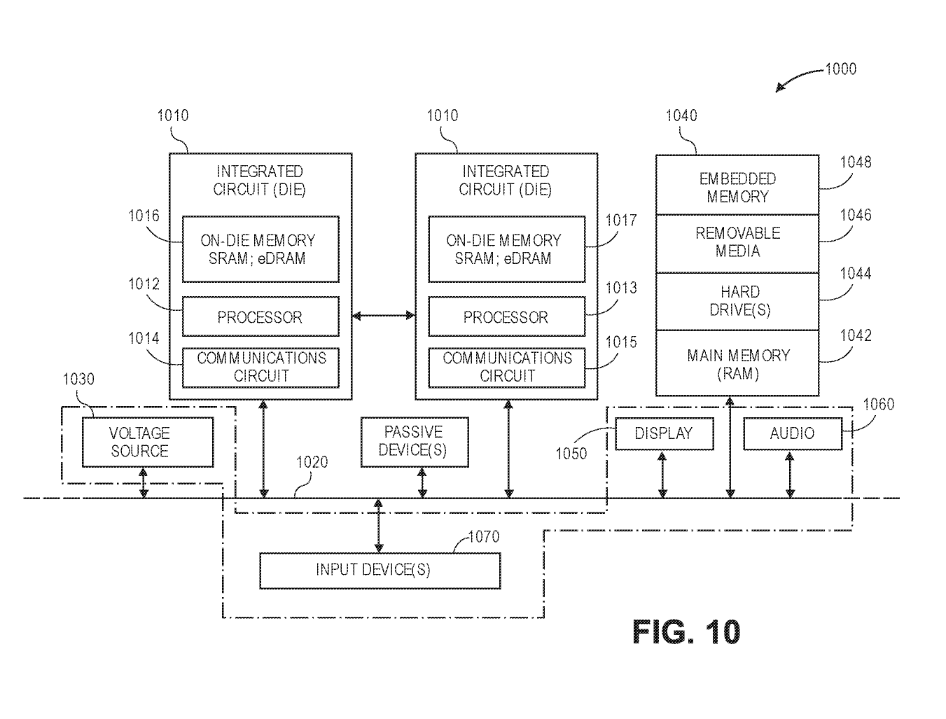

FIG. 10 is a schematic of a computer system, in accordance with an embodiment. The computer system 1000 (also referred to as the electronic system 1000) as depicted can embody a BGA component 104 having solder pads 126 of different sizes, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, a BGA component 104 having solder pads 126 of different sizes, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 1010 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including a package substrate having a BGA component 104 having solder pads 126 of different sizes, according to any of the several disclosed embodiments and their equivalents, an electronic system, a computer system, one or more methods of fabricating an integrated circuit, and one or more methods of fabricating an electronic assembly that includes a package substrate having a BGA component 104 having solder pads 126 of different sizes, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a BGA component 104 having solder pads 126 of different sizes embodiments and their equivalents. A foundation substrate may be included, as represented by the dashed line of FIG. 10. Passive devices may also be included, as is also depicted in FIG. 10.

Embodiments of a chip carrier, such as a BGA component, having solder pads of different sizes are described above. In an embodiment, a chip carrier includes a package substrate having a first surface and a second surface, and several solder pads mounted on the first surface in a pattern. The several solder pads may include a set of first solder pads and a set of second solder pads. Each first solder pad may have a first pad dimension across a first pad surface, and each second solder pad may have a second pad dimension across a second pad surface. The second pad dimension may be less than the first pad dimension. Furthermore, the chip carrier may include several bonding pads mounted on the second surface and electrically connected to the several solder pads through the package substrate.

In one embodiment, the pattern includes a grid pattern, and one or more of the second solder pads are between a pair of first solder pads in a row of the grid pattern.

In one embodiment, the set of second solder pads are arranged in a grid block, and the grid block is between the pair of first solder pads in the row of the grid pattern.

In one embodiment, the grid pattern includes an outer column of solder pads, and the grid block is one or more rows inward from the outer column.

In one embodiment, the first pad dimension is greater than 600 microns, and the second pad dimension is less than 500 microns.

In one embodiment, the several solder pads further include a set of third solder pads. Each third solder pad may have a third pad dimension across a third pad surface, and the third pad dimension may be less than the first pad dimension and greater than the second pad dimension.

In one embodiment, the pattern includes a grid pattern, and one or more third solder pads are between a first solder pad and a second solder pad in a row of the grid pattern.

In one embodiment, the one or more third solder pads are arranged in a grid block, and the grid block is between the first solder pad and the second solder pad in the row of the grid pattern.

In one embodiment, the grid block includes one or more columns of third solder pads. The one or more columns of third solder pads may be between a column of first solder pads having the first solder pad and a column of second solder pads having the second solder pad.

In an embodiment, an integrated circuit package includes a chip carrier and an integrated circuit. The chip carrier may include a package substrate having a first surface and a second surface, and several solder pads mounted on the first surface in a pattern. The several solder pads may include a set of first solder pads and a set of second solder pads. Each first solder pad may have a first pad dimension across a first pad surface, and each second solder pad may have a second pad dimension across a second pad surface. The second pad dimension may be less than the first pad dimension. The chip carrier may include several bonding pads mounted on the second surface and electrically connected to the several solder pads through the package substrate. The integrated circuit may have several pins electrically connected to the several bonding pads, and the pins may be electrically connected to the several solder pads through the several bonding pads.

In one embodiment, the pattern includes a grid pattern, and one or more second solder pads are between a pair of first solder pads in a row of the grid pattern.

In one embodiment, the first pad dimension is greater than 600 microns, and the second pad dimension is less than 500 microns.

In one embodiment, the integrated circuit includes a first signal pin electrically connected to a first solder pad and a second signal pin electrically connected to a second solder pad. The integrated circuit may be configured to deliver a first electrical signal having a first frequency through the first signal pin and a second electrical signal having a second frequency through the second signal pin. The second frequency may be higher than the first frequency.

In one embodiment, a return loss of the second electrical signal delivered to the second solder pad from the second signal pin is more than 15 dB when the second frequency is in a range of 20 GHz to 40 GHz.

In one embodiment, a first insertion loss of the first electrical signal delivered to the first solder pad from the first signal pin is 0.4 dB more than a second insertion loss of the second electrical signal delivered to the second solder pad from the second signal pin when the first electrical signal and the second electrical signal both have a frequency of 16 GHz.

In an embodiment, a method includes forming a set of first solder pads on a first surface of a package substrate, and forming a set of second solder pads on the first surface of the package substrate. Each first solder pad may have a first pad dimension across a first pad surface, and each second solder pad may have a second pad dimension across a second pad surface. The second pad dimension may be less than the first pad dimension. The method may further include attaching a solder ball to each of the first pad surfaces and the second pad surfaces.

In one embodiment, the first pad dimension is greater than 600 microns, and the second pad dimension is less than 500 microns.

In one embodiment, the method includes forming a set of third solder pads on the first surface of the package substrate. Each third solder pad may have a third pad dimension across a third pad surface. The third pad dimension may be less than the first pad dimension and greater than the second pad dimension.

In one embodiment, the method includes forming a plurality of bonding pads on a second surface of the package substrate. The bonding pads may be electrically connected to the first solder pads and the second solder pads. The method may further include coupling several pins of an integrated circuit to the bonding pads to electrically connect the pins to the solder balls through the first solder pads and the second solder pads.

In one embodiment, the method includes delivering a first electrical signal through a first signal pin of the integrated circuit electrically connected to a first solder pad, and delivering a second electrical signal through a second signal pin of the integrated circuit electrically connected to a second solder pad. The second electrical signal may have a higher frequency than the first electrical signal.

What is claimed is:

1. A chip carrier, comprising:
a package substrate having a first surface and a second surface;
a plurality of solder pads mounted on the first surface in a pattern, wherein the plurality of solder pads includes
a set of first solder pads, each first solder pad having a first pad dimension across a first pad surface, and
a set of second solder pads, each second solder pad having a second pad dimension across a second pad surface, wherein the second pad dimension is less than the first pad dimension; and
a plurality of bonding pads mounted on the second surface and electrically connected to the plurality of solder pads through the package substrate.

2. The chip carrier of claim 1, wherein the pattern includes a grid pattern, and wherein one or more of the second solder pads are between a pair of first solder pads in a row of the grid pattern.

3. The chip carrier of claim 2, wherein the set of second solder pads are arranged in a grid block, and wherein the grid block is between the pair of first solder pads in the row of the grid pattern.

4. The chip carrier of claim 3, wherein the grid pattern includes an outer column of solder pads, and wherein the grid block is one or more rows inward from the outer column.

5. The chip carrier of claim 1, wherein the first pad dimension is greater than 600 microns, and wherein the second pad dimension is less than 500 microns.

6. The chip carrier of claim 5, wherein the plurality of solder pads further include a set of third solder pads, each third solder pad having a third pad dimension across a third pad surface, and wherein the third pad dimension is less than the first pad dimension and greater than the second pad dimension.

7. The chip carrier of claim 6, wherein the pattern includes a grid pattern, and wherein one or more third solder pads are between a first solder pad and a second solder pad in a row of the grid pattern.

8. The chip carrier of claim 7, wherein the one or more third solder pads are arranged in a grid block, and wherein the grid block is between the first solder pad and the second solder pad in the row of the grid pattern.

9. The chip carrier of claim 8, wherein the grid block includes one or more columns of third solder pads, and wherein the one or more columns of third solder pads are between a column of first solder pads having the first solder pad and a column of second solder pads having the second solder pad.

10. An integrated circuit package, comprising:
a chip carrier including:
a package substrate having a first surface and a second surface;
a plurality of solder pads mounted on the first surface in a pattern, wherein the plurality of solder pads includes
a set of first solder pads, each first solder pad having a first pad dimension across a first pad surface, and
a set of second solder pads, each second solder pad having a second pad dimension across a second pad surface, wherein the second pad dimension is less than the first pad dimension;
a plurality of bonding pads mounted on the second surface and electrically connected to the plurality of solder pads through the package substrate; and
an integrated circuit having a plurality of pins electrically connected to the plurality of bonding pads, wherein the pins are electrically connected to the plurality of solder pads through the plurality of bonding pads.

11. The integrated circuit package of claim 10, wherein the pattern includes a grid pattern, and wherein one or more second solder pads are between a pair of first solder pads in a row of the grid pattern.

12. The integrated circuit package of claim 10, wherein the first pad dimension is greater than 600 microns, and wherein the second pad dimension is less than 500 microns.

13. The integrated circuit package of claim 10, wherein the integrated circuit includes a first signal pin electrically connected to a first solder pad and a second signal pin electrically connected to a second solder pad, wherein the integrated circuit is configured to deliver a first electrical signal having a first frequency through the first signal pin and a second electrical signal having a second frequency through the second signal pin, the second frequency being higher than the first frequency.

14. The integrated circuit package of claim 13, wherein a return loss of the second electrical signal delivered to the second solder pad from the second signal pin is more than 15 dB when the second frequency is in a range of 20 GHz to 40 GHz.

15. The integrated circuit package of claim 14, wherein a first insertion loss of the first electrical signal delivered to the first solder pad from the first signal pin is 0.4 dB more than a second insertion loss of the second electrical signal delivered to the second solder pad from the second signal pin when the first electrical signal and the second electrical signal both have a frequency of 16 GHz.

16. A method, comprising:
forming a set of first solder pads on a first surface of a package substrate, each first solder pad having a first pad dimension across a first pad surface;
forming a set of second solder pads on the first surface of the package substrate, each second solder pad having a second pad dimension across a second pad surface, wherein the second pad dimension is less than the first pad dimension; and
attaching a solder ball to each of the first pad surfaces and the second pad surfaces.

17. The method of claim 16, wherein the first pad dimension is greater than 600 microns, and wherein the second pad dimension is less than 500 microns.

18. The method of claim 17 further comprising forming a set of third solder pads on the first surface of the package substrate, each third solder pad having a third pad dimension across a third pad surface, wherein the third pad dimension is less than the first pad dimension and greater than the second pad dimension.

19. The method of claim 17 further comprising:
forming a plurality of bonding pads on a second surface of the package substrate, wherein the bonding pads are electrically connected to the first solder pads and the second solder pads; and
coupling a plurality of pins of an integrated circuit to the bonding pads to electrically connect the pins to the solder balls through the first solder pads and the second solder pads.

20. The method of claim 19 further comprising:
delivering a first electrical signal through a first signal pin of the integrated circuit electrically connected to a first solder pad; and
delivering a second electrical signal through a second signal pin of the integrated circuit electrically connected to a second solder pad, wherein the second electrical signal has a higher frequency than the first electrical signal.
